(19) United States
(12) Patent Application Publication
(10) Pub. No.: US 2025/0348633 A1
(43) Pub. Date: Nov. 13, 2025

(54) SYSTEMS AND METHODS FOR GENERATING ASSISTIVE INFORMATION FOR PRESENTATION BASED ON ANALYSIS OF USER ACTIONS AND ACTION MODELS

(71) Applicant: Lenovo Global Technology (United States) Inc., Morrisville, NC (US)

(72) Inventors: Song Wang, Morrisville, NC (US); Kevin Beck, Morrisville, NC (US); Mengnan Wang, Morrisville, NC (US); Russell VanBlon, JR., Morrisville, NC (US)

(21) Appl. No.: 18/659,652

(22) Filed: May 9, 2024

(51) Int. Cl. G06F 30/20

(52) U.S. Cl. CPC G06F 30/20

(57) ABSTRACT

Systems and methods for generating assistive information for presentation based on analysis of user actions and action models are disclosed. According to an aspect, a system includes a computing device comprising a process assistant configured to receive user profile and/or environmental conditions. The process assistant is also configured to receive a model indicative of actions to be taken by a person for implementing a process. Further, the process assistant is configured to acquire data indicative of a person's actions taken for actual implementation of the process. The process assistant is also configured to interpret the person's actions for implementing the process. Further, the process assistant is configured to analyze the interpreted actions of the person and the model indicative of actions to be taken by the user. The process assistant is also configured to generate one or more assistive information for presentation to the user based on the analysis.

### TECHNICAL FIELD

The presently disclosed subject matter relates generally to generating and presentation of assistive information. Particularly, the presently disclosed subject matter relates to systems and methods for generating assistive information for presentation based on analysis of user actions and action models.

### BACKGROUND

Computer vision technologies are utilized to analyze images or video for producing numerical or symbolic information. This information can then be used to derive meaningful information from the images or video to take actions or make recommendations based on the information. Example applications of computer vision includes use with autonomous vehicles, facial recognition, medical imaging, agriculture, manufacturing, and retail.

In an application, computer vision technology is used to analyze a person's actions to determine if a sequence of actions for a process are out of order, have missing steps, or incorrect actions. This technology can be used to assess a person's actions and provide feedback to improve performance. Such feedback is typically provided in post processing, such as in event analysis and statistical reports. In contrast, real time feedback is limited to just replay of previously recorded tutorials or manuals. This type of approach is often considered impersonal and unhelpful.

In view of the foregoing, there is a need for improved systems and techniques that provide assistive information and feedback to users to improve their actions when implementing processes.

### BRIEF DESCRIPTION OF THE DRAWINGS

Having thus described the presently disclosed subject matter in general terms, reference will now be made to the accompanying Drawings, which are not necessarily drawn to scale, and wherein:

FIG. 1 is a block diagram of a system for generating assistive information for presentation based on analysis of user actions and action models in accordance with embodiments of the present disclosure;

FIG. 2 is a flow diagram of a method for generating assistive information for presentation based on analysis of user actions and action models in accordance with embodiments of the present disclosure;

FIG. 3 is a flow diagram of another method for generating assistive information for presentation based on analysis of user actions and action models in accordance with embodiments of the present disclosure;

FIGS. 4A and 4B are images of an example step of an original training data set and an example replacement step generated based on a user's profile, respectively, in accordance with embodiments of the present disclosure; and

FIG. 5 is a flow diagram for recognizing user characteristic differences and generating assistive information based on the differences in accordance with embodiments of the present disclosure.

### SUMMARY

The presently disclosed subject matter relates to systems and methods for generating assistive information for presentation based on analysis of user actions and action models. According to an aspect, a system includes a computing device comprising a process assistant configured to receive user profile and/or environmental conditions. The process assistant is also configured to receive a model indicative of actions to be taken by a person for implementing a process. Further, the process assistant is configured to acquire data indicative of a person's actions taken for actual implementation of the process. The process assistant is also configured to interpret the person's actions for implementing the process. Further, the process assistant is configured to analyze the interpreted actions of the person and the model indicative of actions to be taken by the user. The process assistant is also configured to generate one or more assistive information for presentation to the user based on the analysis.

### DETAILED DESCRIPTION

The following detailed description is made with reference to the figures. Exemplary embodiments are described to illustrate the disclosure, not to limit its scope, which is defined by the claims. Those of ordinary skill in the art will recognize a number of equivalent variations in the description that follows.

Articles “a” and “an” are used herein to refer to one or to more than one (i.e. at least one) of the grammatical object of the article. By way of example, “an element” means at least one element and can include more than one element.

“About” is used to provide flexibility to a numerical endpoint by providing that a given value may be “slightly above” or “slightly below” the endpoint without affecting the desired result.

The use herein of the terms “including,” “comprising,” or “having,” and variations thereof is meant to encompass the elements listed thereafter and equivalents thereof as well as additional elements. Embodiments recited as “including,” “comprising,” or “having” certain elements are also contemplated as “consisting essentially of” and “consisting” of those certain elements.

Unless otherwise defined, all technical terms used herein have the same meaning as commonly understood by one of ordinary skill in the art to which this disclosure belongs.

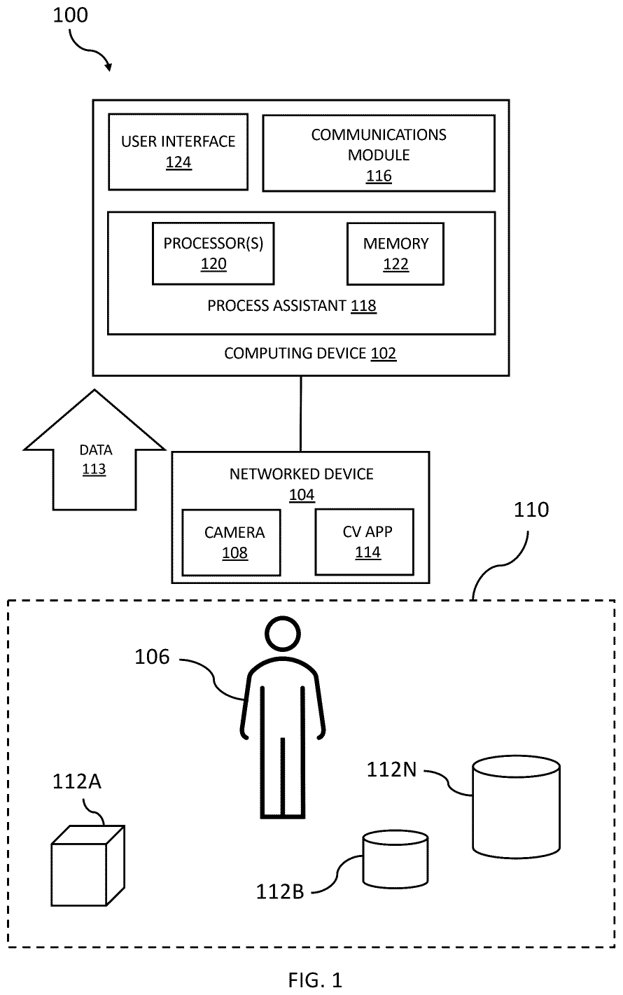

FIG. 1 illustrates a block diagram of a system 100 for generating assistive information for presentation based on analysis of user actions and action models in accordance with embodiments of the present disclosure. Referring to FIG. 1, the system includes a computing device 102 that is communicatively connected to a networked device 104 (e.g., an Internet of Things (IoT) device). The networked device 104 can be operable to acquire data indicative of a person's 106 action taken for actual implementation of a process. For example, the networked device 104 may include a camera 108 operable to capture one or more images (e.g., still images and/or video or other sequence of images) of the person 106 and to store the image data and/or video data. The captured images can include an environment, generally designated with reference number 110, of the person 106. The environment 110 may be a workspace or other area within which the person 106 is taking actions to implement the process.

The captured image(s) may include all or a portion of the person 106 such that the position and/or movement(s) of the person 106 may be recognized, such as by a computer vision technique or other suitable technique. For example, an arm of the person 106 may be recognized and its positioning and movement interpreted. In a particular example, a computer vision technique may receive multiple images of the person 106 and recognize that the person's arm is moving from one side to another, or being raised.

Further, the captured image(s) may be used to deduce and identify the person's 106 interaction with one or more objects 112A-112N within the environment 110. For example, a computer vision technique may be used to recognize objects 112A-112N (“N” is intended to indicate that any number of objects may be present and recognized), and that the person 106 is interacting with one of the objects (e.g., moving one of the objects, or otherwise changing a position or condition of the object). The person's 106 interaction with the object(s) 112A-112N may be a step in a process that the person 106 is implementing.

Environmental conditions may be determined based on the captured image(s). For example, a computer vision technique may be used to identify the object(s) 112A-112N and their positioning or orientation with respect to each other. The identified positioning or orientation of the object(s) 112A-112N can be used to determine a process being implemented or a current step in the process being implemented. This information can be used to determine a next step in the process to be implemented by the person 106.

The networked device 104 may include a computer vision application 114 configured to implement the aforementioned computer vision techniques. Particularly, for example, the computer vision application 114 may be configured to recognize (or identify) the person 106 and object(s) 112A-112N. In addition, the computer vision application 114 can determine the conditions of the environment 110, and can determine actions of the person 106. Alternatively, as described in more detail herein, the computing device 102 may include functionalities for implementing these computer vision techniques based on data in the captured images of the person 106 and the environment 110. The computer vision application 114 can be implemented by suitable hardware, software, and/or firmware (e.g., one or more processors and memory).

The networked device 104 can communicate the captured image(s) and/or data (depicted by arrow 113) generated by the CV application 114 to the computing device 102. This data may be communicated from the networked device 104 to the computing device 102 via any suitable communications network (e.g., local area network, Internet, etc.). The computing device 102 includes a communications module for receiving the data and also for sending data via the communications network.

The computing device 102 includes a process assistant 118 for generating assistive information for presentation to a user based on analysis of actions of a person for implementing a process and based on a model indicative of actions to be taken by a person for implementing the process. To implement its functionalities, the process assistant 118 can receive user profile and/or environmental condition information, receive the model, and data about the person's actions. The process assistant 118 can subsequently interpret the person's actions for implementing the process, analyze the interpreted actions of the person and the model, and generate one or more assistive information for presentation to the user based on the analysis.

The process assistant 118 can include hardware, software, and/or firmware for implementing its functionalities described herein. For example, the process assistant 118 can include one or more processors 120 and memory 122. The processor(s) 120 and memory 122 may be part of the computing device 102 that are used for implementing the computing device's other functionalities. The computing device 102 may be, for example, a smartphone, tablet computer, desktop computer, server, or laptop computer.

The computing device 102 includes a user interface 124 for presenting data and/or images to a user, and for receiving input from the user. For example, the user interface 124 can include, but is not limited to, a display (e.g., touchscreen display), a keyboard, a mouse, or the like. The user interface 124 can be utilized by a user (i.e., an operator of the computing device 102, or the person 106) for initiating the process assistant 118 and for interacting with the process assistant 118 in accordance with embodiments of the present disclosure.

A user of the computing device 102 can utilize the user interface 124 to initiate the process assistant 118. Subsequently, the user interface 124 can be used to enter user profile and/or environmental conditions. For example, the profile of the person 106 can be entered via the user interface 124. Also, for example, the user interface 124 can be used to enter conditions of the environment 110. The user can also use the user interface 124 to identify a process that is being implemented by the person 106. This information (e.g., user profile, environmental conditions, and identification of the process) can be communicated to and received by the process assistant 118.

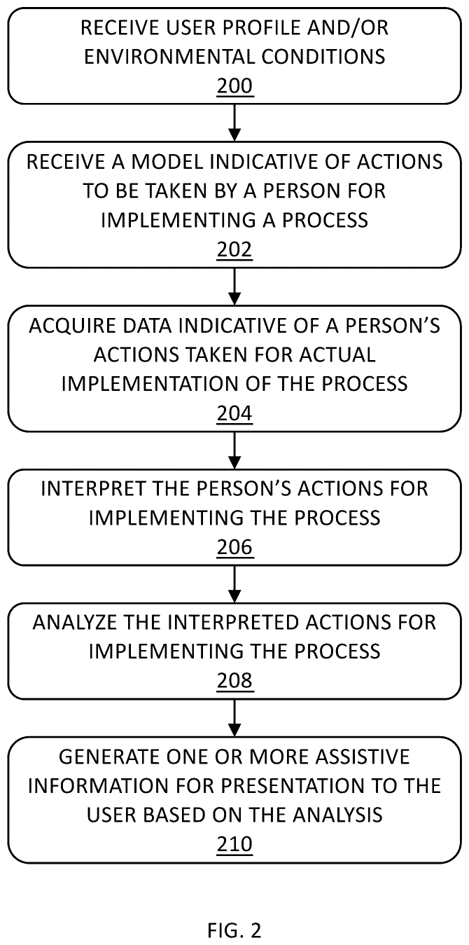

Now turning to FIG. 2, this figure illustrates a method for generating assistive information for presentation based on analysis of user actions and action models in accordance with embodiments of the present disclosure. The method of FIG. 2 is described by example as being implemented by the system 100 shown in FIG. 1. Although, it should be understood that the method may be implemented by any other suitable system or suitably configured computing device.

The method of FIG. 2 includes receiving 200 user profile and/or environmental conditions. For example, the user of the computing device 102 can enter user profile and environmental condition information via the user interface 124. The user profile information can, for example, indicate characteristics and/or capabilities of the person 106. For example, the profile information can indicate the person's 106 physical capabilities and preferences for implementing a process in the environment. Physical capabilities information can include, but is not limited to, a lifting maximum (e.g., weight lifting limit), right or left hand preference, working time preference, and the like. Environmental conditions information can include, but is not limited to, a location, time, positioning of objects within the environment, equipment features, and the like. This data can be input via the user interface 124 or otherwise received by the computing device 102 such as via a network. Further, this data can be suitably received and stored by the process assistant 118.

The method of FIG. 2 includes receiving 202 a model indicative of a person's actions for implementing the process. Continuing the aforementioned example, the process assistant 118 can receive a model indicative of a person's actions for implementing the process. For example, the model can include a sequence of actions and/or a manner of the actions to be taken by a person for implementing a process. The actions can be movements to be taken by the person, such as movements of the person's arms, interactions with objects (e.g., objects 112A-112N), and an ordering or manner of these actions. The model can be associated with a manufacturing process, a medical process, and the like.

The method of FIG. 2 includes acquiring 204 data indicative of a person's actions taken for actual implementation of the process. Continuing the aforementioned example, the process assistant 118 can receive data 113 from the networked device 104. The data 113 can be indicative of the person's 106 actions taken for actual implementation of the process. For example, the camera 108 of the networked device 104 can capture images of the person 106 while the person 106 is taking actions for implementing a process. The actions can include movements, positioning, and interactions with one or more of the objects 112A-112N. A computer vision technique or another suitable technique implemented by the computer vision application 114, the process assistant 118, in combination or apart, can function to determine a sequence of the actions, a manner of the actions, or the like taken by the person 106. Data indicative of these actions can be received and stored in memory 122 of the process assistant 118.

The method of FIG. 2 includes interpreting 206 the person's actions for implementing the process. Continuing the aforementioned example, the process assistant 118 can interpret the person's actions for implementing the process. For example, the process assistant 118 can analyze data indicative of the person's 106 actions. The analysis can be based on the determined sequence of the actions and/or manner of the actions taken by the person 106 for actual implementation of the process. This interpretation can be used for comparison to the model for determining whether the person's actual actions are in accordance with the model.

The method of FIG. 2 includes analyzing 208 the interpreted actions of the person and the model indicative of actions to be taken by the user. Continuing the aforementioned example, the process assistant 118 can analyze the interpreted actions of the person 106 as compared to the model for determining whether there is a discrepancy with the model's actions. The process assistant 118 can determine whether the actions of the person 106 are ordered the same as the actions in the model for determining that there is a discrepancy. For example, there can be a discrepancy in the case of steps of the actions being different in sequence or missing a step. Also, the process assistant 118 can determine whether any of the person's 106 actions are in a different manner than the actions in the model for determining that there is a discrepancy. For example, there can be a discrepancy in the case of a step of the actions being implemented in a different manner.

The method of FIG. 2 includes generating 210 one or more assistive information for presentation to the user based on the analysis. Continuing the aforementioned example, the process assistant 118 can generate a presentation (e.g., text, images, and/or video) to indicate the person's 106 discrepancies of actions as compared to the model. This information can be presented to the person 106 via the user interface 124 or another user interface to inform the person 106 where his or her actions deviated from the model. The presentation can indicate how the actions are different. Conversely, the presentation can indicate to the person 106 where the actions and/or sequence of actions are alike. Such information can be beneficial for training the person 106 on implementing the process.

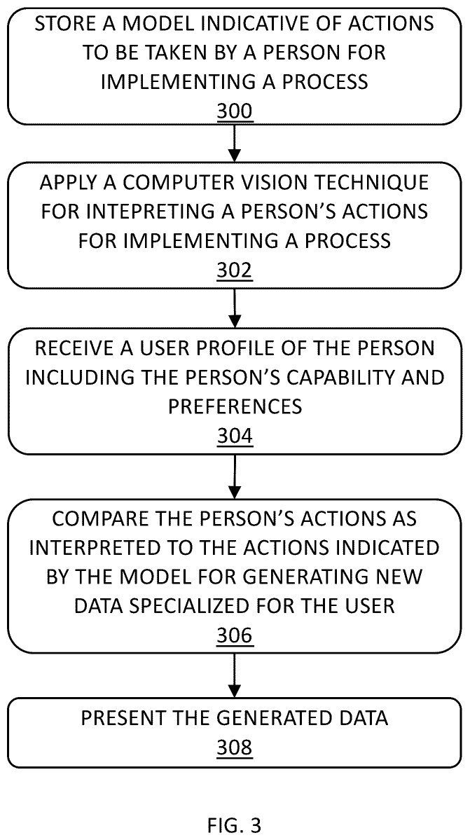

FIG. 3 illustrates another method for generating assistive information for presentation based on analysis of user actions and action models in accordance with embodiments of the present disclosure. The method of FIG. 3 is described by example as being implemented by the system 100 shown in FIG. 1. Although, it should be understood that the method may be implemented by any other suitable system or suitably configured computing device.

The method of FIG. 3 includes storing 300 a model indicative of actions to be taken by a person for implementing a process. For example, the process assistant 118 can store in its memory 122 a model of actions for a process.

The method of FIG. 3 includes applying 302 a computer vision technique for interpreting a person's actions for implementing a process. Continuing the aforementioned example, the process assistant 118 can implement a computer vision technique to interpret a sequence of actions and manner of the actions taken by the person 106 for implementing the process. In an example, the networked device 104 can acquire images of the person 106 implementing various actions for a process. The image data can be communicated to the computing device 102 where the process assistant 118 applies the computer vision technique. The computer vision technique can identify the person 106, actions of the person 106, and a sequence of the actions.

The method of FIG. 3 includes receiving 304 a user profile of the person including the person's capability and preferences. Continuing the aforementioned example, information about the person's 106 profile and capability can be received and stored in memory 122.

The method of FIG. 3 includes comparing 306 the person's actions as interpreted to the actions indicated by the model. Continuing the aforementioned example, the process assistant 118 can compare the person's 106 actions to the model for determining discrepancies. In an example, once discrepancies are detected generative artificial intelligence (AI) can be used to create a new set of data with information pertaining specifically to the user (his or her characteristics as indicated by the user profile, context, etc.). This AI generated data can be in the form of images, video, voice synthesis, the like, and/or combinations thereof.

The method of FIG. 3 includes presenting 308 the generated data to the person. Continuing the aforementioned example, the process assistant 118 can utilize the user interface 124 for presenting the AI generated data to the user.

In accordance with embodiments, collection of data about actions of the person can be implemented by any suitable technique. For example, an augmented reality (AR) headset, IoT device, or the like can be used. This collected data can be fed into a generative AI-implemented device. For example, the process assistant 118 of the computing device can implement such AI techniques.

In an example scenario such as a manufacturing environment, a set of training data can be used to detect or determine discrepancies in a worker's assembly steps and correctness of installation. User profile information in accordance with embodiments of the present disclosure can be used to account for a user's individual characteristics, such as whether the worker is left-handed, handicapped, etc. Under such circumstances, the process assistant 118 can use the worker's physical characteristics as indicated by the profile combined with model data for generating a new set of assistive or corrective steps that are designed for the specific worker. For a left-handed worker, it may be that a toolset position is switched between left and right hands. Other examples of data to be used include a user's height, weight, eyesight, etc. that can affect the way model instructions or tutorials are performed and also provide a presentation about the same.

In other embodiments, contextual information can utilized to determine when a task should be performed or a manner of its performance. For example, contextual information may include, but is not limited to, a time of day and a person's current schedule. This information can be used by an AI technique to determine when the task is best performed by the person. In the example of an AR headset with depth sensing capabilities, the process assistant 118 can determine in real time the environmental structure data which determines whether the working location is ideal or new work areas are needed for the task or process.

In other embodiments, a user's preference data obtained from nearby devices can be used as data for generative AI service. These data include, but are not limited to, device settings such as brightness, fonts, and the like. The newly generated content can be displayed in a way that is based on the user's personal preference.

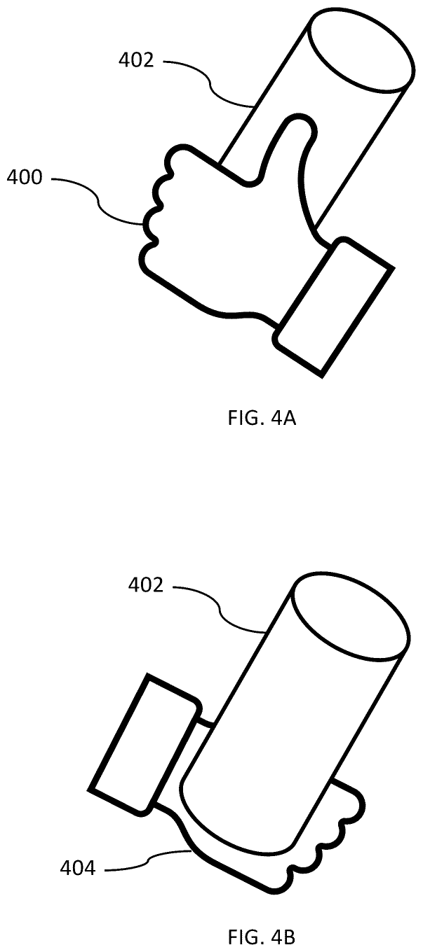

FIGS. 4A and 4B illustrate images of an example step of an original training data set and an example replacement step generated based on a user's profile, respectively, in accordance with embodiments of the present disclosure. Referring to FIG. 4A, this figure shows a step in a sequence of training images (or video) in which a person's hand 400 is shown moving an object 402. In this original training set, the hand 400 is a right hand of the person depicted in the sequence of training images, which is part of a model indicative of actions to be taken by a person for implementing a process.

With continuing reference to FIGS. 4A and 4B, a process assistant can determine that the actual person implementing the process is left handed based on a received user profile for the person. Subsequently and based on this profile information, the process assistant can generate replacement assistive information for presentation to the person based on the analysis. Particularly, to replace the depicted step of FIG. 4A, the process assistant can generate the replacement step image shown in FIG. 4B. In the image of FIG. 4B, it can be seen that a left hand 404 is shown engaging the object 402. The process assistant generated this replacement image to depict the left hand 404 for an improved depiction of how it would appear to the actual user who is left handed. The process assistant can, for example, utilize AI to remove the hand 400 shown in FIG. 4A and replace the hand 400 with a left hand 404. The image of the object 402 can be retained in the newly generated image. This new image in the sequence can be used in the assistive information for presentation to the user. Other images can be similarly generated and used for presentation to the user.

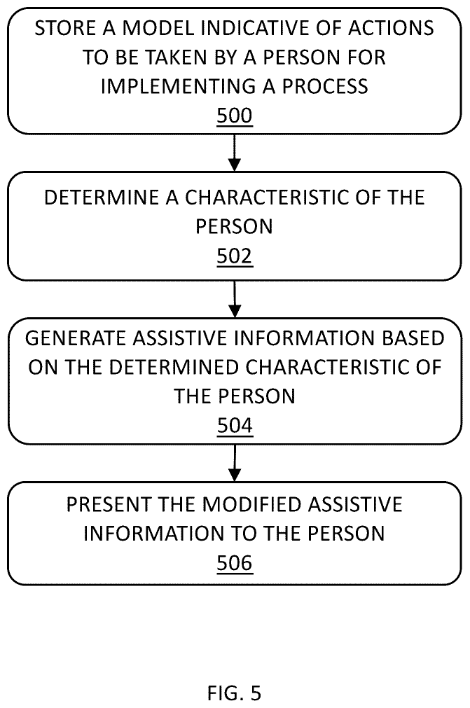

In accordance with embodiments, FIG. 5 is a flow diagram for recognizing user characteristic differences and generating assistive information based on the differences. The method of FIG. 5 is described by example as being implemented by the system 100 shown in FIG. 1. Although, it should be understood that the method may be implemented by any other suitable system or suitably configured computing device.

Referring to FIG. 5, the method includes storing 500 a model indicative of actions to be taken by a person for implementing a process. For example, the process assistant 118 can store in its memory 122 a model of actions for a process.

The method of FIG. 5 includes determining 502 a characteristic of the person. Continuing the aforementioned example, the process assistant 118 can determine a characteristic of the person. For example, the process assistant 118 can analyze profile information, an image, a video, or other data to determine a characteristic of the person. In an example, the process assistant 118 can recognize that the person is missing appendages, such as fingers or an arm. Further, the process assistant can recognize that the training data set is designed for person's having a different number of appendages. Therefore, the process assistant 118 can take this information into account for generating a new training data set.

The method of FIG. 5 includes generating 504 assistive information based on the determined characteristic of the person. Continuing the aforementioned example, the process assistant 118 can modify one or more steps in the training data set to adjust for the different number of appendages (e.g. fingers) of the person. This adjustment can include modifying one or more steps and/or adding one or more steps.

The method of FIG. 5 includes presenting 506 the modified assistive information to the person. Continuing the aforementioned example, the process assistant 118 can use a user interface to present the modified assistive information to the person. The modified assistive information can be presented via one of or any combination of the following: text, voice synthesized speech, images, animation, or videos with AI-generated images and/or actions.

The functional units described in this specification have been labeled as computing devices. A computing device may be implemented in programmable hardware devices such as processors, digital signal processors, central processing units, field programmable gate arrays, programmable array logic, programmable logic devices, cloud processing systems, or the like. The computing devices may also be implemented in software for execution by various types of processors. An identified device may include executable code and may, for instance, comprise one or more physical or logical blocks of computer instructions, which may, for instance, be organized as an object, procedure, function, or other construct. Nevertheless, the executable of an identified device need not be physically located together but may comprise disparate instructions stored in different locations which, when joined logically together, comprise the computing device and achieve the stated purpose of the computing device. In another example, a computing device may be a server or other computer located within a retail environment and communicatively connected to other computing devices (e.g., POS equipment or computers) for managing accounting, purchase transactions, and other processes within the retail environment. In another example, a computing device may be a mobile computing device such as, for example, but not limited to, a smart phone, a cell phone, a pager, a personal digital assistant (PDA), a mobile computer with a smart phone client, or the like. In another example, a computing device may be any type of wearable computer, such as a computer with a head-mounted display (HMD), or a smart watch or some other wearable smart device. Some of the computer sensing may be part of the fabric of the clothes the user is wearing. A computing device can also include any type of conventional computer, for example, a laptop computer or a tablet computer. A typical mobile computing device is a wireless data access-enabled device (e.g., an iPHONE® smart phone, an iPAD® device, smart watch, or the like) that is capable of sending and receiving data in a wireless manner using protocols like the Internet Protocol, or IP, and the wireless application protocol, or WAP. This allows users to access information via wireless devices, such as smart watches, smart phones, mobile phones, pagers, two-way radios, communicators, and the like. Wireless data access is supported by many wireless networks, including, but not limited to, Bluetooth, Near Field Communication, CDPD, CDMA, GSM, PDC, PHS, TDMA, FLEX, ReFLEX, iDEN, TETRA, DECT, DataTAC, Mobitex, EDGE and other 2G, 3G, 4G, 5G, and LTE technologies, and it operates with many handheld device operating systems, such as PalmOS, EPOC, Windows CE, FLEXOS, OS/9, JavaOS, iOS and Android. Typically, these devices use graphical displays and can access the Internet (or other communications network) on so-called mini-or micro-browsers, which are web browsers with small file sizes that can accommodate the reduced memory constraints of wireless networks. In a representative embodiment, the mobile device is a cellular telephone or smart phone or smart watch that operates over GPRS (General Packet Radio Services), which is a data technology for GSM networks or operates over Near Field Communication e.g. Bluetooth. In addition to a conventional voice communication, a given mobile device can communicate with another such device via many different types of message transfer techniques, including Bluetooth, Near Field Communication, SMS (short message service), enhanced SMS (EMS), multi-media message (MMS), email WAP, paging, or other known or later-developed wireless data formats. Although many of the examples provided herein are implemented on smart phones, the examples may similarly be implemented on any suitable computing device, such as a computer.

An executable code of a computing device may be a single instruction, or many instructions, and may even be distributed over several different code segments, among different applications, and across several memory devices. Similarly, operational data may be identified and illustrated herein within the computing device, and may be embodied in any suitable form and organized within any suitable type of data structure. The operational data may be collected as a single data set, or may be distributed over different locations including over different storage devices, and may exist, at least partially, as electronic signals on a system or network.

The described features, structures, or characteristics may be combined in any suitable manner in one or more embodiments. In the following description, numerous specific details are provided, to provide a thorough understanding of embodiments of the disclosed subject matter. One skilled in the relevant art will recognize, however, that the disclosed subject matter can be practiced without one or more of the specific details, or with other methods, components, materials, etc. In other instances, well-known structures, materials, or operations are not shown or described in detail to avoid obscuring aspects of the disclosed subject matter.

As used herein, the term “memory” is generally a storage device of a computing device. Examples include, but are not limited to, read-only memory (ROM) and random access memory (RAM).

The device or system for performing one or more operations on a memory of a computing device may be a software, hardware, firmware, or combination of these. The device or the system is further intended to include or otherwise cover all software or computer programs capable of performing the various heretofore-disclosed determinations, calculations, or the like for the disclosed purposes. For example, exemplary embodiments are intended to cover all software or computer programs capable of enabling processors to implement the disclosed processes. Exemplary embodiments are also intended to cover any and all currently known, related art or later developed non-transitory recording or storage mediums (such as a CD-ROM, DVD-ROM, hard drive, RAM, ROM, floppy disc, magnetic tape cassette, etc.) that record or store such software or computer programs. Exemplary embodiments are further intended to cover such software, computer programs, systems and/or processes provided through any other currently known, related art, or later developed medium (such as transitory mediums, carrier waves, etc.), usable for implementing the exemplary operations disclosed below.

In accordance with the exemplary embodiments, the disclosed computer programs can be executed in many exemplary ways, such as an application that is resident in the memory of a device or as a hosted application that is being executed on a server and communicating with the device application or browser via a number of standard protocols, such as TCP/IP, HTTP, XML, SOAP, REST, JSON and other sufficient protocols. The disclosed computer programs can be written in exemplary programming languages that execute from memory on the device or from a hosted server, such as BASIC, COBOL, C, C++, Java, Pascal, or scripting languages such as JavaScript, Python, Ruby, PHP, Perl, or other suitable programming languages.

As referred to herein, the terms “computing device” and “entities” should be broadly construed and should be understood to be interchangeable. They may include any type of computing device, for example, a server, a desktop computer, a laptop computer, a smart phone, a cell phone, a pager, a personal digital assistant (PDA, e.g., with GPRS NIC), a mobile computer with a smartphone client, or the like.

As referred to herein, a user interface is generally a system by which users interact with a computing device. A user interface can include an input for allowing users to manipulate a computing device, and can include an output for allowing the system to present information and/or data, indicate the effects of the user's manipulation, etc. An example of a user interface on a computing device (e.g., a mobile device) includes a graphical user interface (GUI) that allows users to interact with programs in more ways than typing. A GUI typically can offer display objects, and visual indicators, as opposed to text-based interfaces, typed command labels or text navigation to represent information and actions available to a user. For example, an interface can be a display window or display object, which is selectable by a user of a mobile device for interaction. A user interface can include an input for allowing users to manipulate a computing device, and can include an output for allowing the computing device to present information and/or data, indicate the effects of the user's manipulation, etc. An example of a user interface on a computing device includes a graphical user interface (GUI) that allows users to interact with programs or applications in more ways than typing. A GUI typically can offer display objects, and visual indicators, as opposed to text-based interfaces, typed command labels or text navigation to represent information and actions available to a user. For example, a user interface can be a display window or display object, which is selectable by a user of a computing device for interaction. The display object can be displayed on a display screen of a computing device and can be selected by and interacted with by a user using the user interface. In an example, the display of the computing device can be a touch screen, which can display the display icon. The user can depress the area of the display screen where the display icon is displayed for selecting the display icon. In another example, the user can use any other suitable user interface of a computing device, such as a keypad, to select the display icon or display object. For example, the user can use a track ball or arrow keys for moving a cursor to highlight and select the display object.

The display object can be displayed on a display screen of a mobile device and can be selected by and interacted with by a user using the interface. In an example, the display of the mobile device can be a touch screen, which can display the display icon. The user can depress the area of the display screen at which the display icon is displayed for selecting the display icon. In another example, the user can use any other suitable interface of a mobile device, such as a keypad, to select the display icon or display object. For example, the user can use a track ball or times program instructions thereon for causing a processor to carry out aspects of the present disclosure.

As referred to herein, a computer network may be any group of computing systems, devices, or equipment that are linked together. Examples include, but are not limited to, local area networks (LANs) and wide area networks (WANs). A network may be categorized based on its design model, topology, or architecture. In an example, a network may be characterized as having a hierarchical internetworking model, which divides the network into three layers: access layer, distribution layer, and core layer. The access layer focuses on connecting client nodes, such as workstations to the network. The distribution layer manages routing, filtering, and quality-of-server (QoS) policies. The core layer can provide high-speed, highly-redundant forwarding services to move packets between distribution layer devices in different regions of the network. The core layer typically includes multiple routers and switches.

The present subject matter may be a system, a method, and/or a computer program product. The computer program product may include a computer readable storage medium (or media) having computer readable program instructions thereon for causing a processor to carry out aspects of the present subject matter.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a RAM, a ROM, an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network, or Near Field Communication. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present subject matter may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Java, Smalltalk, C++, Javascript or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present subject matter.

Aspects of the present subject matter are described herein with reference to flowchart illustrations and/or block diagrams of methods, apparatus (systems), and computer program products according to embodiments of the subject matter. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present subject matter. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the embodiments have been described in connection with the various embodiments of the various figures, it is to be understood that other similar embodiments may be used, or modifications and additions may be made to the described embodiment for performing the same function without deviating therefrom. Therefore, the disclosed embodiments should not be limited to any single embodiment, but rather should be construed in breadth and scope in accordance with the appended claims.

What is claimed is:

1. A system comprising:
a computing device comprising a process assistant configured to:
receive user profile and/or environmental conditions;
receive a model indicative of actions to be taken by a person for implementing a process;
acquire data indicative of a person's actions taken for actual implementation of the process;
interpret the person's actions for implementing the process;
analyze the interpreted actions of the person and the model indicative of actions to be taken by the user; and
generate one or more assistive information for presentation to the user based on the analysis.

2. The system of claim 1, wherein the computing device comprises a user interface configured to receive user input indicative of the user profile and/or the environmental conditions.

3. The system of claim 1, further comprising a networked device configured to:
acquire data indicative of the user profile and/or the environmental conditions; and
communicate, to the computing, the acquired data device indicative of the user profile and/or the environmental conditions.

4. The system of claim 1, wherein the model indicates a sequence of the actions and/or a manner of the actions to be taken by the person for implementing the process.

5. The system of claim 1, further comprising a networked device configured to:
acquire data indicative of the person's actions taken for actual implementation of the process; and
communicate, to the computing, the acquired data device indicative of the person's actions taken for actual implementation of the process.

6. The system of claim 1, wherein the process assistant is configured to determine a sequence of the actions and/or a manner of the actions taken by the person for actual implementation of the process.

7. The system of claim 6, wherein the process assistant is configured to analyze the interpreted actions of the person based on the determined sequence of the actions and/or manner of the actions taken by the person for actual implementation of the process.

8. The system of claim 1, wherein the process assistant is configured to:
analyze the interpreted actions of the person for determining a discrepancy with the model indicative of actions to be taken by the user; and
generate the one or more assistive information based on the discrepancy.

12. The system of claim 1, wherein the process assistant is configured to utilize a user interface to present the one or more assistive information.

13. The system of claim 1, wherein the one or more assistive information indicates at least one action, an order of actions, and/or a manner of action for implementing the process.

14. The system of claim 13, wherein the at least one action, an order of actions, and/or a manner of action for implementing the process are different than actions, order of actions, and/or manner of actions indicated by the model.

15. The system of claim 1, wherein the process assistant is configured to apply a computer vision technique for interpreting the person's actions for implementing the process.

16. The system of claim 1, wherein the user profile indicates a capability of the person and/or preferences of the person, and
wherein the process assistant is configured to generate the one or more assistive information based on the capability of the person and/or preferences of the person.

17. The system of claim 1, wherein the environmental conditions indicate a location and/or time, and
wherein the process assistant is configured to generate the one or more assistive information based on the capability of the person.

18. A method comprising:
receiving, via a computing device, user profile and/or environmental conditions;
receiving, via the computing device, a model indicative of actions to be taken by a person for implementing a process;
acquiring, via the computing device, data indicative of a person's actions taken for actual implementation of the process;
interpreting, via the computing device, the person's actions for implementing the process;
analyzing, via the computing device, the interpreted actions of the person and the model indicative of actions to be taken by the user; and
generating, via the computing device, one or more assistive information for presentation to the user based on the analysis.

19. The method of claim 18, further comprising using a user interface to present the one or more assistive information.

20. The method of claim 18, wherein the model indicates a sequence of the actions and/or a manner of the actions to be taken by the person for implementing the process.
